(19) United States
(12) Patent Application Publication
(10) Pub. No.: US 2026/0243923 A1
(43) Pub. Date: Aug. 20, 2026

(54) MULTILAYER METASURFACE SUPERLENS AND SURFACE PLASMON LITHOGRAPHY METHOD

(71) Applicant: INSTITUTE OF MICROELECTRONICS, CHINESE ACADEMY OF SCIENCES, Beijing (CN)

(72) Inventors: Jianfang He, Beijing (CN); Yayi Wei, Beijing (CN); Yajuan Su, Beijing (CN); Huwen Ding, Beijing (CN)

(21) Appl. No.: 19/372,734

(22) Filed: Oct. 29, 2025

(30) Foreign Application Priority Data
Feb. 20, 2025 (CN) 202510190178.5

(51) Int. Cl. G02B 1/00; G02B 3/02; G03F 1/54; G03F 7/00

(52) U.S. Cl. CPC G02B 1/007; G02B 3/02; G03F 1/54; G03F 7/70316

(57) ABSTRACT

The present application discloses a multilayer metasurface superlens and a surface plasmon lithography method, which can be used in the field of semiconductor manufacturing. The multilayer metasurface superlens comprises: a substrate, a mask absorption layer, a filling layer, a first metal-dielectric composite film, and a second metal-dielectric composite film stacked in sequence. The mask absorption layer and the filling layer are in contact with the dielectric side of the first metal-dielectric composite film. The metal layers in the first metal-dielectric composite film and the second metal-dielectric composite film are made of the same metal. The material of the metal layers is any one selected from the group consisting of titanium, tantalum, titanium nitride, and copper. The projection of the mask absorption layer on a surface of the substrate is a periodically arranged pattern.

This application claims priority to Chinese Patent Application No. 202510190178.5, titled “MULTILAYER METASURFACE SUPERLENS AND SURFACE PLASMON LITHOGRAPHY METHOD,” filed on Feb. 20, 2025 with the China National Intellectual Property Administration, which is incorporated herein by reference in its entirety.

### FIELD

The present disclosure relates to the technical field of semiconductor manufacturing, and in particular to a multilayer metasurface superlens and a surface plasmon lithography method.

### BACKGROUND

As integrated circuit process nodes shrink, imaging fine structures in large-scale integrated circuit processes has drawn increasing attention.

Surface plasmon lithography (SPL) is a lithography method that utilizes surface plasmon polaritons (SPPs) for high-resolution patterning. The SPL can utilize specially designed metal films to couple and propagate evanescent waves, enabling imaging of fine structures with features sizes far smaller than the wavelength. However, silver, the primary metal used in SPL, is chemically unstable and easily diffuses during the lithography process, which can lead to contamination and negatively impact the reliability of the integrated circuit.

Thus, how to integrate SPL with the large-scale integrated circuit processes remains a challenge to be solved.

### SUMMARY

To address the above-mentioned issues, the present disclosure provides a multilayer metasurface superlens and a surface plasmon lithography method, which can achieve the integration of surface plasmon lithography technology with large-scale integrated circuit processes.

The embodiments of the present disclosure disclose the following technical solutions.

In a first aspect, an embodiment of the present disclosure provides a multilayer metasurface superlens, comprising: a substrate, a mask absorption layer, a filling layer, a first metal-dielectric composite film, and a second metal-dielectric composite film;
where the substrate, the mask absorption layer, the filling layer, the first metal-dielectric composite film, and the second metal-dielectric composite film are stacked in sequence, and the mask absorption layer and the filling layer are in contact with a dielectric side of the first metal-dielectric composite film;
a metal layer in the first metal-dielectric composite film and a metal layer in the second metal-dielectric composite film are made of a same metal, a material of the metal layers is any one selected from the group consisting of titanium, tantalum, titanium nitride, and copper; and
a projection of the mask absorption layer on a surface of the substrate is a periodically arranged pattern.

Optionally, the projection of the mask absorption layer on a surface of the substrate is periodically arranged lines.

Optionally, the periodically arranged pattern has a period of 260 nm.

Optionally, in both the first metal-dielectric composite film and the second metal-dielectric composite film, the material of the dielectric layer is titanium dioxide.

Optionally, the mask absorption layer and the filling layer have a same thickness.

Optionally, the mask absorption layer has a thickness of 40 nm.

Optionally, the mask absorption layer is a chromium layer.

Optionally, in the first metal-dielectric composite film and the second metal-dielectric composite film, the metal layer has a thickness of 10 nm and the dielectric layer has a thickness of 20 nm.

Optionally, the mask absorption layer has a sidewall angle of 0°.

In a second aspect, an embodiment of the present disclosure provides a surface plasmon lithography method, comprising:
providing TM-polarized light having a wavelength of 365 nm as incident light; transferring a pattern in the multilayer metasurface superlens to a surface of a to-be-lithographed structure based on the incident light being incident normally from the substrate side of the multilayer metasurface superlens described in any embodiment of the first aspect; where the to-be-lithographed structure comprises a wafer, a metal reflective layer, and a mask layer stacked in sequence, the mask layer is located at a side adjacent to the second metal-dielectric composite film in the multilayer metasurface superlens described in any embodiment of the first aspect; and the material of the metal reflective layer is any one selected from the group consisting of titanium, tantalum, titanium nitride, and copper.

Compared to the conventional art, the present disclosure has the following advantages:

The present disclosure provides a multilayer metasurface superlens, comprising: a substrate, a mask absorption layer, a filling layer, a first metal-dielectric composite film, and a second metal-dielectric composite film; where the substrate, the mask absorption layer, the filling layer, the first metal-dielectric composite film, and the second metal-dielectric composite film are stacked in sequence, and the mask absorption layer and the filling layer are in contact with a dielectric side of the first metal-dielectric composite film; a metal layer in the first metal-dielectric composite film and a metal layer in the second metal-dielectric composite film are made of a same metal, a material of the metal layers is any one selected from the group consisting of titanium, tantalum, titanium nitride, and copper; and a projection of the mask absorption layer on a surface of the substrate is a periodically arranged pattern. Thus, the multilayer metasurface superlens with a high-stability metal material is provided. The surface plasmon lithography is performed based on the multilayer metasurface superlens provided in the embodiment of the present disclosure. Surface plasmons are excited by a hyperbolic metamaterial composed of the metal-dielectric composite films. Surface plasmon near-field lithography imaging based on an optical negative-refraction material can avoid contamination of the to-be-etched integrated circuit structure due to metal diffusion in the multilayer metasurface superlens, and is friendly to the integrated circuit process. Furthermore, based on the multilayer film lens provided in embodiments of the present disclosure, the surface plasmon lithography technology can be applied in the integrated circuit manufacturing process to achieve the integration of surface plasmon lithography technology and large-scale integrated circuit technology.

### BRIEF DESCRIPTION OF THE DRAWINGS

To illustrate technical solutions in the embodiments of the present disclosure or the conventional art more clearly, hereinafter drawings used in the embodiments or conventional art descriptions are briefly described. Apparently, the drawings described below are only some embodiments of the present application, and other drawings may be obtained by those skilled in the art based on the provided drawings without exerting creative efforts.

FIG. 1 is a schematic structural diagram of a multilayer metasurface superlens according to an embodiment of the present disclosure.

FIG. 2 is a schematic diagram of imaging results using a silver-based multilayer metasurface superlens according to an embodiment of the present disclosure.

FIG. 3 is a schematic diagram of imaging results using a titanium-based multilayer metasurface superlens according to an embodiment of the present disclosure.

FIG. 4 is a schematic diagram of imaging results using a tantalum-based multilayer metasurface superlens according to an embodiment of the present disclosure.

FIG. 5 is a schematic diagram of imaging results using a titanium nitride-based multilayer metasurface superlens according to an embodiment of the present disclosure.

FIG. 6 is a schematic diagram of imaging results using a copper-based multilayer metasurface superlens according to an embodiment of the present disclosure.

FIG. 7 is a flow chart of a surface plasmon lithography method according to an embodiment of the present disclosure.

FIG. 8 is a schematic diagram of a to-be-lithographed structure according to an embodiment of the present disclosure.

### DETAILED DESCRIPTION OF EMBODIMENTS

provided by the present disclosure can be used in the field of semiconductor manufacturing. The above description is merely illustrative and does not limit application areas of the multilayer metasurface superlens and surface plasmon lithography method provided by the present disclosure.

The terms “first”, “second”, “third” and “fourth” in the specification, claims, and accompanying drawings are used to distinguish between different objects and are not intended to limit a specific order.

In the embodiments of the present disclosure, expressions such as “as an example” or “for example” are used to indicate examples, illustrations, or explanations. Any embodiment or design described as “as an example” or “for example” in the embodiments of the present disclosure should not be construed as preferred or advantageous over other embodiments or designs. Rather, the use of expressions such as “as an example” or “for example” is intended to present the relevant concepts in a specific manner.

The terms used in the embodiments of the present disclosure are intended only to explain the specific embodiments of the present disclosure and are not intended to limit the present disclosure.

To make those skilled in the art better understand the present disclosure, hereinafter the technical solutions in the embodiments of the present disclosure are described clearly and completely in conjunction with the drawings in the embodiments of the present disclosure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

A multilayer metasurface superlens is an optical element designed based on the concept of metamaterials. It utilizes nanoscale structures to manipulate light waves, enabling precise control of light properties such as phase, amplitude, and polarization. The multilayer metasurface superlens can surpass the traditional diffraction limit and provide higher resolution than traditional optical lenses.

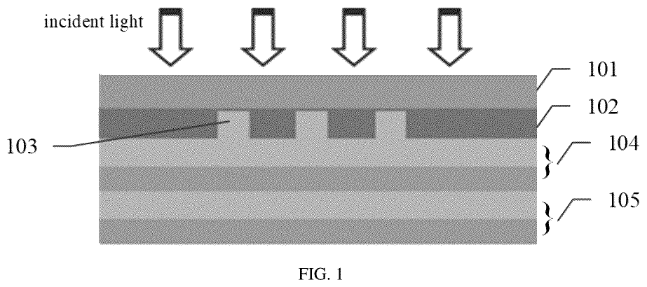

Reference is made to FIG. 1, which is a schematic structural diagram of the multilayer metasurface superlens according to an embodiment of the present disclosure. The multilayer metasurface superlens comprises a substrate 101, a mask absorption layer 102, a filling layer 103, a first metal-dielectric composite film 104, and a second metal-dielectric composite film 105.

The substrate 101, the mask absorption layer 102, the filling layer 103, the first metal-dielectric composite film 104, and the second metal-dielectric composite film 105 are stacked in sequence. The mask absorption layer 102 and the filling layer 103 are in contact with a dielectric side of the first metal-dielectric composite film 104. The mask absorption layer 102 and the filling layer 103 have a same thickness. The filling layer 103 is for filling gaps in the pattern formed by the mask absorption layer 102 to reduce optical interference caused by uneven surfaces.

The metal layers in the first metal-dielectric composite film 104 and the second metal-dielectric composite film 105 are made of the same metal. The material of the metal layers may be selected from the group consisting of the titanium, tantalum, titanium nitride, and copper.

The projection of the mask absorption layer 102 on a surface of the substrate 101 is a periodically arranged pattern. The material of the mask absorption layer 102 may be chromium.

Hyperbolic Metamaterials (HMMs) are artificially designed composite structures whose permittivity is positive in one direction and negative in another, resulting in the isofrequency contour exhibiting a hyperbolic shape. The unique dielectric properties of hyperbolic metamaterials enable them to support extraordinary electromagnetic modes on the subwavelength scale, such as extremely high effective refractive index or negative refraction.

In one embodiment, the first metal-dielectric composite film 104 and the second metal-dielectric composite film 105 are stacked. The metal layer is made of titanium, tantalum, titanium nitride, or copper, all of which exhibit a negative effective permittivity (ε<0) in the ultraviolet region. The dielectric layer may be made of titanium dioxide (TiO₂), a high-refractive-index medium with a positive effective permittivity (ε>0) in the ultraviolet region. A multilayer structure with anisotropic permittivity is constructed by alternately stacking the metal layers and the dielectric layer, which forms the hyperbolic metamaterial.

When light is irradiated onto the HMMs composed of the first metal-dielectric composite film 104 and the second metal-dielectric composite film 105, surface plasmons may be excited. The surface plasmons may propagate within the material and produce negative refraction at specific locations, which can simulate the effect of a negative refractive index material, compensate for the loss of evanescent waves and reconstruct high-resolution images, thereby allowing light to be focused onto a very small point and achieving a nanometer-scale resolution.

Optionally, the projections of the mask absorption layer 102 on a surface of the substrate 101 are periodically arranged lines.

Optionally, the line may have a width of 130 nm, and the arrangement period is smaller than but close to the wavelength of the incident light to induce diffraction effects. To achieve high-resolution and high-contrast patterns using surface plasmon lithography, when the incident light is TM-polarized light with a wavelength of 365 nm, the arrangement period may be 260 nm.

Optionally, the dielectric layer material in both the first metal-dielectric composite film 104 and the second metal-dielectric composite film 105 is titanium dioxide.

Optionally, the metal layer in both the first metal-dielectric composite film 104 and the second metal-dielectric composite film 105 has a thickness of 10 nm, and the dielectric layer has a thickness of 20 nm.

Optionally, the mask absorption layer 102 has a thickness of 40 nm and a sidewall angle of 0° to ensure clearly defined pattern edges and achieve high-precision lithography.

Therefore, in one embodiment, the multilayer metasurface superlens with a high-stability metal material is provided. The surface plasmon lithography is performed based on the multilayer metasurface superlens provided in embodiments of the present disclosure. Surface plasmons are excited by the hyperbolic metamaterial composed of the metal-dielectric composite films. Surface plasmon near-field lithography imaging based on an optical negative-refraction material can avoid contamination of the to-be-etched integrated circuit structure due to metal diffusion in the multilayer metasurface superlens, and is friendly to the integrated circuit process. Furthermore, based on the multilayer metasurface lens provided in embodiments of the present disclosure, surface plasmon lithography technology can be applied in the integrated circuit manufacturing process to achieve the integration of surface plasmon lithography technology and large-scale integrated circuit technology.

In addition, in the multilayer metasurface superlens structure according to an embodiment of the present disclosure, titanium, tantalum, copper, or titanium nitride is selected as the material for the metal layer in the metal-dielectric composite film. Compared to silver, the material improves the imaging contrast of surface plasmon lithography.

Software FDTD solutions can be used to model and simulate the optical behavior of light in the multilayer metasurface superlens provided by the present disclosure. The electric field intensity of the aerial image at the center of the mask layer in the to-be-lithographed structure after surface plasmon lithography may be calculated to evaluate the imaging performance. In one embodiment, all components in the y-direction are considered infinite to simplify the computational model and ignore finite-size effects in the y-direction.

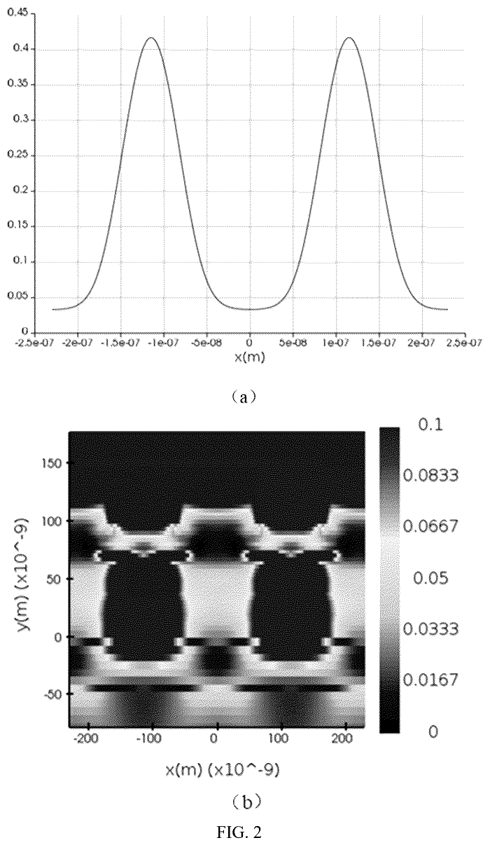

Reference is made to FIG. 2, which is imaging results of the silver-based multilayer metasurface superlens according to an embodiment of the present disclosure and may be obtained by simulating using the FDTD (Finite-Difference Time-Domain) method.

In FIG. 2, (a) shows the imaging curve of the aerial image in the mask layer in the x-z direction, with the horizontal axis representing the position and the vertical axis representing light intensity, wherein the aerial image curve in the x-z direction is for describing the variation of light intensity along the lateral direction (x-direction) and perpendicular to the surface of the substrate 101 (z-direction). The curve provides information about the position of the focal point, the intensity distribution, and the imaging resolution.

In FIG. 2, (b) shows a two-dimensional thermal map of the imaging light intensity distribution in the x-y plane. Both the horizontal and vertical axes represent the position. The observation position of the aerial image in the mask layer is at y=25 nm on the y-axis. The color change in the figure illustrates the intensity distribution at different positions. Referring to the color scale on the right, the blue color indicates low intensity, and the red color indicates high intensity.

Image contrast C=(Iₘₐₓ−Iₘᵢₙ) /I_{avg}, where Iₘₐₓ is the average light intensity in the maximum intensity region, Iₘᵢₙ is the average light intensity in the minimum intensity region, and I_{avg} is the average light intensity across the entire image region.

Based on the imaging contrast calculation formula and the imaging results of the silver-based multilayer metasurface superlens shown in FIG. 2, when silver is selected as the metal layer material in the metal-dielectric composite film, the imaging contrast C_{Ag} of the multilayer metasurface superlens can be calculated using the software FDTD solutions, with C_{Ag}=0.85.

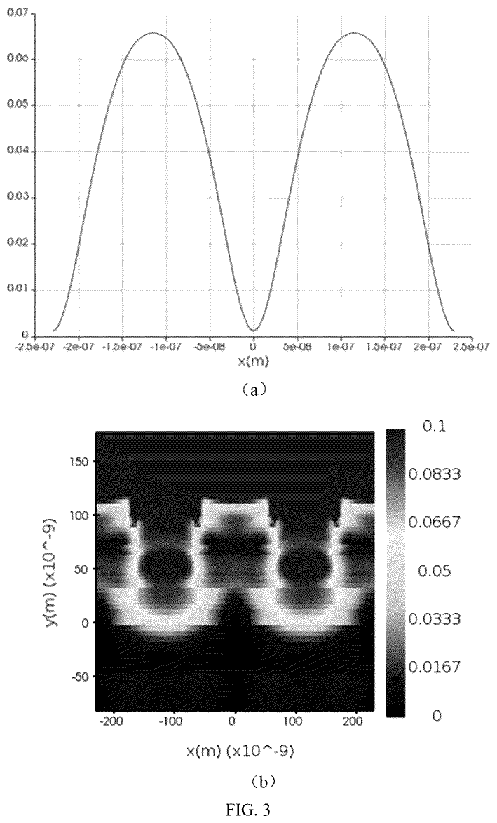

Reference is made to FIG. 3, which is imaging results of the titanium-based multilayer metasurface superlens according to an embodiment of the present disclosure and may be obtained by simulating using the FDTD (Finite-Difference Time-Domain) method.

In FIG. 3, (a) shows the imaging curve of the aerial image in the mask layer in the x-z direction, with the horizontal axis representing the position and the vertical axis representing light intensity. In FIG. 3, (b) shows a two-dimensional thermal map of the imaging light intensity distribution in the x-y plane. Both the horizontal and vertical axes represent the position. The observation position of the aerial image in the mask layer is at y=25 nm on the y-axis. The color change in the figure illustrates the intensity distribution at different positions. Referring to the color scale on the right, the blue color indicates low intensity, and the red color indicates high intensity.

Based on the imaging contrast calculation formula and the imaging results of the titanium-based multilayer metasurface superlens shown in FIG. 3, when titanium is selected as the metal layer material in the metal-dielectric composite film, the imaging contrast C_{Ti} of the multilayer metasurface superlens can be calculated using the software FDTD solutions, with C_{Ti}=0.96.

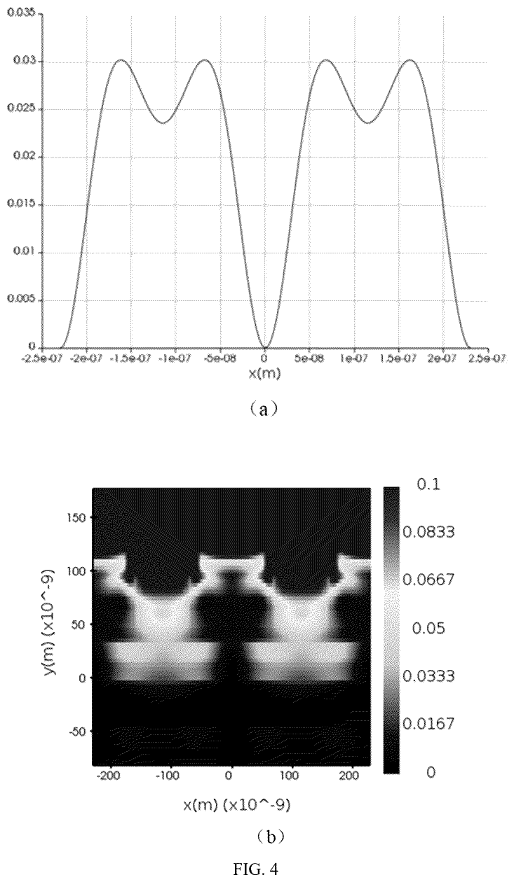

Reference is made to FIG. 4, which is imaging results of the tantalum-based multilayer metasurface superlens according to an embodiment of the present disclosure and may be obtained by simulating using the FDTD (finite-difference time-domain) method.

In FIG. 4, (a) shows the imaging curve of the aerial image in the mask layer in the x-z direction, with the horizontal axis representing the position and the vertical axis representing light intensity. In FIG. 4, (b) shows a two-dimensional thermal map of the imaging light intensity distribution in the x-y plane. Both the horizontal and vertical axes represent the position. The observation position of the aerial image in the mask layer is at y=25 nm on the y-axis. The color change in the figure illustrates the intensity distribution at different positions. Referring to the color scale on the right, the blue color indicates low intensity, and the red color indicates high intensity.

Based on the imaging contrast calculation formula and the imaging results of the tantalum-based multilayer metasurface superlens shown in FIG. 4, when tantalum is selected as the metal layer material in the metal-dielectric composite film, the imaging contrast C_{Ta} of the multilayer metasurface superlens can be calculated using the software FDTD solutions, with C_{Ta}=0.99.

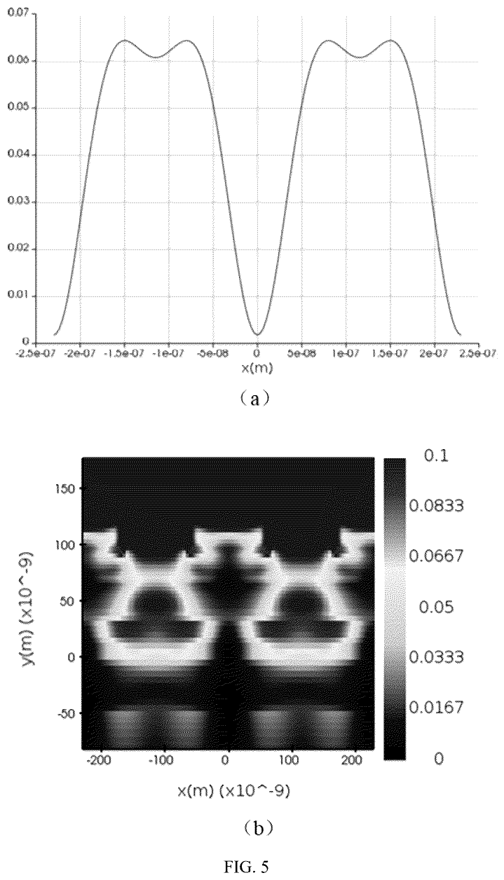

Reference is made to FIG. 5, which is imaging results of the titanium nitride-based multilayer metasurface superlens according to an embodiment of the present disclosure and may be obtained by simulating using the FDTD (finite-difference time-domain) method.

In FIG. 5, (a) shows the imaging curve of the aerial image in the mask layer in the x-z direction, with the horizontal axis representing the position and the vertical axis representing light intensity. In FIG. 5, (b) shows a two-dimensional thermal map of the imaging light intensity distribution in the x-y plane. Both the horizontal and vertical axes represent the position. The observation position of the aerial image in the mask layer is at y=25 nm on the y-axis. The color change in the figure illustrates the intensity distribution at different positions. Referring to the color scale on the right, the blue color indicates low intensity, and the red color indicates high intensity.

Based on the imaging contrast calculation formula and the imaging results of the titanium nitride-based multilayer metasurface superlens shown in FIG. 5, when titanium nitride is selected as the metal layer material in the metal-dielectric composite film, the imaging contrast C_{TiN} of the multilayer metasurface superlens can be calculated using the software FDTD solutions, with C_{TiN}=0.95.

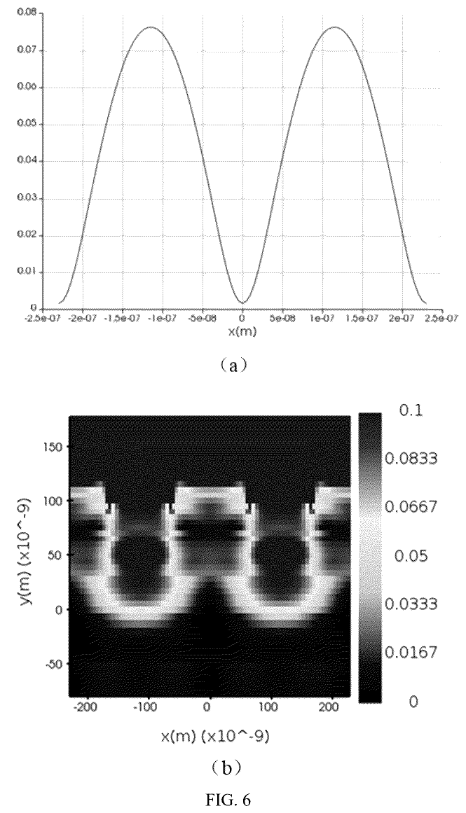

Reference is made to FIG. 6, which is imaging results of the copper-based multilayer metasurface superlens according to an embodiment of the present disclosure and may be obtained by simulating using the FDTD (finite-difference time-domain) method.

In FIG. 6, (a) shows the imaging curve of the aerial image in the mask layer in the x-z direction, with the horizontal axis representing the position and the vertical axis representing light intensity. In FIG. 6, (b) shows a two-dimensional thermal map of the imaging light intensity distribution in the x-y plane. Both the horizontal and vertical axes represent the position. The observation position of the aerial image in the mask layer is at y=25 nm on the y-axis. The color change in the figure illustrates the intensity distribution at different positions. Referring to the color scale on the right, the blue color indicates low intensity, and the red color indicates high intensity.

Based on the imaging contrast calculation formula and the imaging results of the copper-based multilayer metasurface superlens shown in FIG. 6, when copper is selected as the metal layer material in the metal-dielectric composite film, the imaging contrast C_{Cu} of the multilayer metasurface superlens can be calculated using the software FDTD solutions, with C_{Cu}=0.96.

It can be seen from FIG. 2, FIG. 3, FIG. 4, FIG. 5 and FIG. 6, that the multilayer metasurface superlens imaging results and corresponding imaging contrast, compared to the silver as the metal layer material in the metal-dielectric composite film, selecting titanium, tantalum, copper, or titanium nitride as the metal layer material in the metal-dielectric composite film may significantly improve the imaging contrast of surface plasmon lithography, thereby enhancing the imaging resolution of surface plasmon lithography and promoting the integration of surface plasmon lithography technology with large-scale integrated circuit processes.

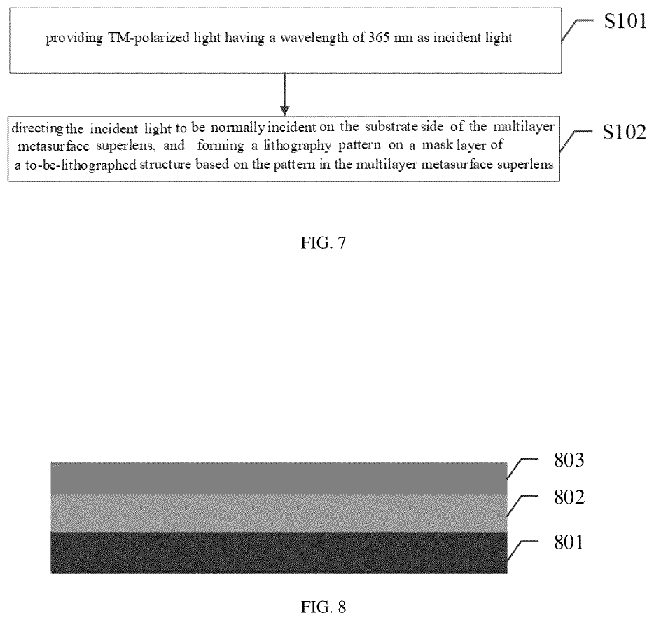

Reference is made to FIG. 7, which is a flow chart of a surface plasmon lithography method according to an embodiment of the present disclosure. The method comprises:

S701: providing TM-polarized light having a wavelength of 365 nm as incident light.

After passing through the multilayer metasurface superlens, the incident light excites surface plasmon waves on the surface of the metal-dielectric composite film. The surface plasmon waves propagate on the surface of the metal-dielectric composite film and are manipulated by the multilayer metasurface superlens to form a specific interference pattern. By adjusting the structural parameters of the multilayer metasurface superlens, such as the thickness of the metal layer and the dielectric layer in the metal-dielectric composite film, precise control of the interference pattern may be achieved, thereby achieving high-precision imaging for surface plasmon lithography.

S702: directing the incident light to be normally incident on the substrate side of the multilayer metasurface superlens according to any one of the above embodiments, and forming a lithography pattern on a mask layer of a to-be-lithographed structure based on the pattern in the multilayer metasurface superlens.

Reference is made to FIG. 8, which is a schematic diagram of a to-be-Lithographed

### Structure According to an Embodiment of the Present Disclosure.

The to-be-lithographed structure comprises a wafer 801, a metal reflective layer 802, and a mask layer 803 stacked in sequence, wherein, the mask layer 803 is located at a side adjacent to the second metal-dielectric composite film 105 in the multilayer metasurface superlens according to any one of the above embodiments.

The material of the metal reflective layer 802 is any one selected from the group consisting of titanium, tantalum, titanium nitride, and copper, and the thickness of the metal reflective layer 802 may be 40 nm.

Optionally, the material of metal reflective layer 802 is the same as that of the metal layers in first metal-dielectric composite film 104 and second metal-dielectric composite film 105.

Optionally, the mask layer 803 is a photoresist layer and has a thickness of 20 nm.

Thus, in the embodiments of the present disclosure, the surface plasmon lithography is performed based on the multilayer metasurface superlens according to any one of the embodiments of the present disclosure. Surface plasmons are excited by a hyperbolic metamaterial composed of the metal-dielectric composite films. Surface plasmon near-field lithography imaging based on an optical negative-refraction material can avoid contamination of the to-be-etched integrated circuit structure due to metal diffusion in the multilayer metasurface superlens, is friendly to the integrated circuit process, and can achieve the integration of surface plasmon lithography technology and large-scale integrated circuit technology.

In addition, a lithography apparatus is further provided by an embodiment of the present disclosure. The apparatus comprises a memory and a processor.

The memory is configured to store program codes and transmit the program codes to the processor.

The processor is configured to execute steps of the surface plasmon lithography method described above according to the program codes.

It should be noted that various embodiments in the specification are described in a progressive manner. References may be made to the common and similar parts between the various embodiments. Each embodiment focuses on the differences from other embodiments. In particular, since the product embodiments are generally similar to the method embodiments, their description is relatively simplified. For relevant parts, references are made to the description of the method embodiments. The product embodiments described above are merely illustrative. The units described as separate components may or may not be physically separate, and the components described as units may or may not be physical units, which may be located in one location or distributed across multiple network units. Some or all of these modules may be selected to achieve objectives of embodiments as needed. Those skilled in the art will be able to understand and implement the embodiments without creative effort.

The foregoing is merely one specific embodiment of the present disclosure, but the scope of protection of the present disclosure is not limited thereto. Any modifications or substitutions that can be readily conceived by those skilled in the art within the technical scope disclosed herein are intended to be covered by the scope of protection of the present disclosure. Therefore, the scope of protection of the the present disclosure should be determined by the scope of claims.

1. A multilayer metasurface superlens, comprising: a substrate, a mask absorption layer, a filling layer, a first metal-dielectric composite film, and a second metal-dielectric composite film;
wherein the substrate, the mask absorption layer, the filling layer, the first metal-dielectric composite film, and the second metal-dielectric composite film are stacked in sequence, and the mask absorption layer and the filling layer are in contact with a dielectric side of the first metal-dielectric composite film;
a metal layer in the first metal-dielectric composite film and a metal layer in the second metal-dielectric composite film are made of a same metal, a material of the metal layers is any one selected from the group consisting of titanium, tantalum, titanium nitride, and copper; and
a projection of the mask absorption layer on the substrate surface is a periodically arranged pattern.

2. The multilayer metasurface superlens according to claim 1, wherein the projection of the mask absorption layer on a surface of the substrate is periodically arranged lines.

3. The multilayer metasurface superlens according to claim 1, wherein the periodically arranged pattern has a period of 260 nm.

4. The multilayer metasurface superlens according to claim 1, wherein in both the first metal-dielectric composite film and the second metal-dielectric composite film, a material of the dielectric layer is titanium dioxide.

5. The multilayer metasurface superlens according to claim 1, wherein the mask absorption layer and the filling layer have a same thickness.

6. The multilayer metasurface superlens according to claim 1, wherein the mask absorption layer has a thickness of 40 nm.

7. The multilayer metasurface superlens according to claim 1, wherein the mask absorption layer is a chromium layer.

8. The multilayer metasurface superlens according to claim 1, wherein in the first metal-dielectric composite film and the second metal-dielectric composite film, the metal layer has a thickness of 10 nm and the dielectric layer has a thickness of 20 nm.

9. The multilayer metasurface superlens according to claim 1, wherein the mask absorption layer has a sidewall angle of 0°.

10. A surface plasmon lithography method, comprising:
providing TM-polarized light having a wavelength of 365 nm as incident light;
directing the incident light to be normally incident on the substrate side of the multilayer metasurface superlens according toclaim 1, and forming a lithography pattern on a mask layer of a to-be-lithographed structure based on the pattern in the multilayer metasurface superlens;
wherein the to-be-lithographed structure comprises a wafer, a metal reflective layer, and a mask layer stacked in sequence, the mask layer is located at a side adjacent to the second metal-dielectric composite film in the multilayer metasurface superlens according to claim 1, and the material of the metal reflective layer is any one selected from the group consisting of titanium, tantalum, titanium nitride, and copper.
